(19) United States
(12) Patent Application Publication
(10) Pub. No.: US 2025/0393370 A1
(43) Pub. Date: Dec. 25, 2025

(54) ANTI-REFLECTION LAYER, DISPLAY DEVICE, AND ELECTRONIC DEVICE INCLUDING THE SAME

(71) Applicant: Samsung Display Co., Ltd., Yongin-Si (KR)

(72) Inventors: Ju Young YOON, Yongin-si (KR); Da Hye KIM, Yongin-si (KR); Hyun Hyang KIM, Yongin-si (KR); Sang Won LEE, Yongin-si (KR); Seong Sik CHOI, Yongin-si (KR)

(21) Appl. No.: 19/231,915

(22) Filed: Jun. 9, 2025

(30) Foreign Application Priority Data
Jun. 19, 2024 (KR) 10-2024-0079518
Aug. 23, 2024 (KR) 10-2024-0113816

(51) Int. Cl. H10H 29/80; G02B 1/115; H10K 59/80

(52) U.S. Cl. CPC H10H 29/842; G02B 1/115; H10K 59/8791

(57) ABSTRACT

An anti-reflection layer includes a substrate layer including a substrate high-refractive layer and a substrate low-refractive layer, and a surface layer disposed on the substrate layer and including a surface high-refractive layer and a surface low-refractive layer. A thickness of the substrate high-refractive layer may be 5 nm to 70 nm, a thickness of the substrate low-refractive layer may be 5 nm to 70 nm, a thickness of the surface high-refractive layer may be 100 nm to 180 nm, and a thickness of the surface low-refractive layer may be 60 nm to 110 nm.

### CROSS-REFERENCE TO RELATED APPLICATIONS

This application claims priority to and the benefit of Korean Patent Application No. 10-2024-0079518 filed in the Korean Intellectual Property Office on Jun. 19, 2024 and Korean Patent Application No. 10-2024-0113816 filed in the Korean Intellectual Property Office on Aug. 23, 2024, the entire contents of which are incorporated herein by reference.

### BACKGROUND

### Field

The present invention relates to an anti-reflection layer, a display device, and an electronic device including the same.

### Description of the Related Art

Recent interest in information display has increased research and development of display devices.

### SUMMARY

In accordance with an aspect of the present disclosure, a high-hardness anti-reflection layer may be provided with excellent optical properties and a display device may include a high-hardness anti-reflection layer having excellent optical properties.

Aspects and objects of the present disclosure are not limited to the aforesaid, and additional aspects, objects, and features of this disclosure be understood by those skilled in the art from descriptions below.

An anti-reflection layer according to an embodiment may include a substrate layer including a substrate high-refractive layer and a substrate low-refractive layer, and a surface layer disposed on the substrate layer and including a surface high-refractive layer and a surface low-refractive layer. A thickness of the substrate high-refractive layer may be about 5 nm to 70 nm, a thickness of the substrate low-refractive layer may be about 5 nm to 70 nm, a thickness of the surface high-refractive layer may be about 100 nm to 180 nm, and a thickness of the surface low-refractive layer may be about 60 nm to 110 nm.

The display device may further include an intermediate layer disposed between the substrate layer and the surface layer and including a first high-refractive layer and a first low-refractive layer.

A thickness of the first high-refractive layer may be about 20 nm to 600 nm.

A thickness of the first low-refractive layer may be about 5 nm to 30 nm.

The intermediate layer may further include a second high-refractive layer on the first low-refractive layer and a second low-refractive layer on the second high-refractive layer.

A thickness of the second high-refractive layer may be about 20 nm to 600 nm.

A thickness of the second low-refractive layer may be about 5 nm to 30 nm.

A refractive index of each of the substrate high-refractive layer and the surface high-refractive layer may be about 1.9 to 2.3.

A refractive index of each of the substrate low-refractive layer and the surface low-refractive layer may be about 1.4 to 1.7.

A display device according to an embodiment may include a display panel; a substrate layer disposed on the display panel and including a substrate high-refractive layer and a substrate low-refractive layer; and a surface layer disposed on the substrate layer and including a surface high-refractive layer and a surface low-refractive layer. A thickness of the substrate high-refractive layer may be about 5 nm to 70 nm, a thickness of the substrate low-refractive layer may be about 5 nm to 70 nm, a thickness of the surface high-refractive layer may be about 100 nm to 180 nm, and a thickness of the surface low-refractive layer may be about 60 nm to 110 nm.

The display device may further include an intermediate layer disposed between the substrate layer and the surface layer, and including a first high-refractive layer and a first low-refractive layer.

A thickness of the first high-refractive layer may be about 20 nm to 600 nm.

A thickness of the first low-refractive layer may be about 5 nm to 30 nm.

The intermediate layer may further include a second high-refractive layer on the first low-refractive layer and a second low-refractive layer on the second high-refractive layer.

A thickness of the second high-refractive layer may be about 20 nm to 600 nm.

A thickness of the second low-refractive layer may be about 5 nm to 30 nm.

The display device may further include an anti-fingerprint layer on the surface layer.

The display device may further include an adhesive layer between the display panel and the substrate layer.

A thickness of the adhesive layer may be about 10 nm to 70 nm.

A refractive index of the adhesive layer may be about 1.4 to 1.7.

Specific details of other embodiments are included in specification and drawings.

An electronic device according to an embodiment may include a processor to provide input image data; and a display device to display an image based on the input image data, wherein the display device comprises a display panel; a substrate layer disposed on the display panel and including a substrate high-refractive layer and a substrate low-refractive layer; and a surface layer disposed on the substrate layer and including a surface high-refractive layer and a surface low-refractive layer, wherein a thickness of the substrate high-refractive layer is 5 nm to 70 nm, a thickness of the substrate low-refractive layer is 5 nm to 70 nm, a thickness of the surface high-refractive layer is 100 nm to 180 nm, and a thickness of the surface low-refractive layer is 60 nm to 110 nm.

According to the above-described embodiment, the reflectivity of the anti-reflection layer can be reduced, and the hardness thereof can be improved. That is, a high-hardness anti-reflection layer having excellent optical properties and a display device including the same can be provided.

Effects according to embodiments are not limited by contents exemplified above, and more various effects are included in the present specification.

### BRIEF DESCRIPTION OF THE DRAWINGS

FIG. 1 is a perspective view of a display device according to an embodiment.

FIG. 2 is a cross-sectional view of a display device according to an embodiment.

FIGS. 3, 4, 5, and 6 are cross-sectional views of cover layers according to embodiments.

FIG. 7 is a graph showing a relationship of hardness and indentation depth in cover layers according to an embodiment.

FIG. 8 is a plan view of a display panel according to an embodiment.

FIG. 9 is a plan view of a pixel according to an embodiment.

FIG. 10 is a cross-sectional view taken along a line I-I′ of FIG. 9.

FIG. 11 is a block diagram of an electronic device according to an embodiment.

FIG. 12 shows schematic views of various embodiments of an electronic device.

### DETAILED DESCRIPTION OF THE EMBODIMENTS

Example embodiments according to the present invention are described in detail below with reference to the attached drawings. The following description may be limited to the parts necessary to understand operation according to the present disclosure, and description of other parts may be omitted to avoid obscuring important features of the present disclosure. Additionally, embodiments the present disclosure are not limited to the illustrated embodiments described herein, and other embodiments may have other forms. The embodiments described herein are provided to explain in detail enough to enable those skilled in the art to easily implement the technical idea of the present disclosure.

Throughout the specification, a part said to be “connected” to another part includes not only the case where the parts are “directly connected” but also the case where the parts are “indirectly connected” with another element therebetween. In this disclosure, a structure said to “include” some elements means that the structure may include only those elements or may include other elements as well as those elements, unless a specific limitation states otherwise. The phrases “at least one of X, Y, and Z” and “at least one selected from the group consisting of X, Y, and Z” may be interpreted as an X, a Y, a Z, or any combination (e.g., XYZ, XYY, YZ, and ZZ) of two or more among X, Y, and Z. Also, “and/or” includes any combination of one or more of the constituents.

Herein, terms such as first, second, etc. may be used to describe various components, but these components are not limited to these terms. These terms are used only to distinguish one component from another component. Accordingly, the first component may be referred to as the second component within the scope of what is disclosed herein.

Spatially relative terms such as “below,” “above,” etc. may be used for descriptive purposes, thereby describing the relationship of one element or feature to another element(s) or feature(s) as shown in the drawings. Spatially relative terms are intended to include different directions associated with other orientations in use, operation, and/or manufacture in addition to the directions or orientations depicted in the drawings. For example, if the device shown in the drawings is turned over, elements depicted and described as being disposed “below” other elements or features may be disposed “above” the other elements or features. Accordingly, in one embodiment, the term “below” may include both above and below directions. Additionally, objects may be oriented in other directions (e.g., rotated by 90 degrees or in other orientations), and thus the spatially relative terms used herein should be interpreted to depend on the orientation.

Various embodiments are described with reference to drawings that schematize ideal embodiments. Accordingly, shapes and sizes may vary from those shown in the drawings depending, for example, on tolerances and/or manufacturing techniques. Accordingly, the illustrated embodiments disclosed herein should not be construed as being limited to the specific shapes shown and should be construed to include changes in shape that occur, for example, as a result of manufacturing. As such, the shapes shown in the drawings may not depict the actual shapes of areas of the device, and the present embodiments are not limited thereto.

Hereinafter, example embodiments of the present disclosure are described in detail with reference to the drawings.

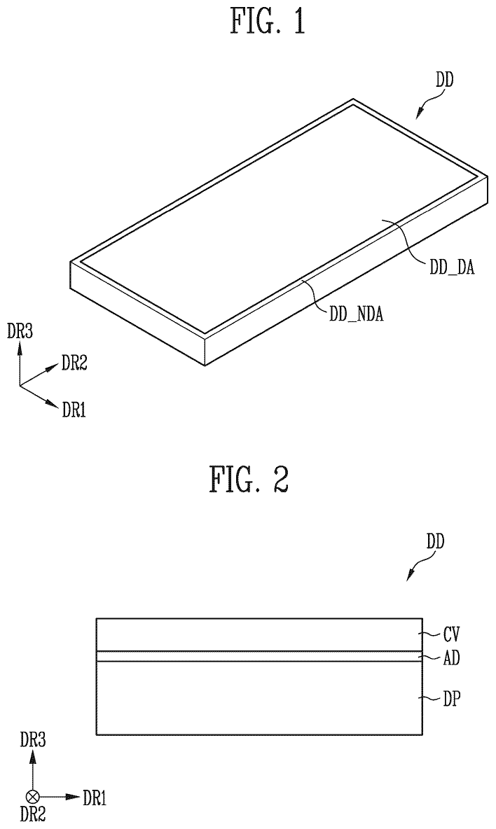

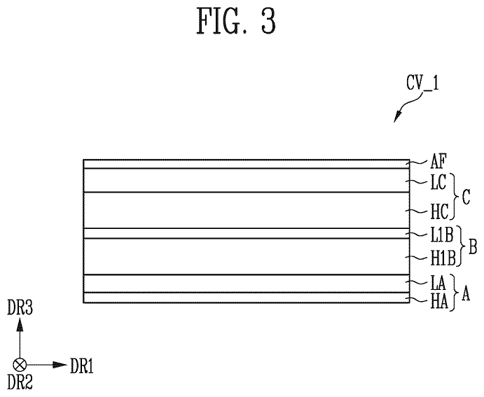

FIG. 1 is a perspective view of a display device DD according to an embodiment. FIG. 2 is a cross-sectional view of an embodiment of the display device. FIGS. 3 to 6 are cross-sectional views showing cover layers according to some embodiments that may be used in some embodiments of the display device DD.

Referring to FIGS. 1 and 2, the display device DD may include a display panel DP, a cover layer CV, and/or an adhesive layer AD.

The display device DD may include a display area DD_DA that displays an image and a non-display area DD_NDA that does not display an image. The non-display area DD_NDA may be provided on at least one side of the display area DD_DA. For example, the non-display area DD_NDA may surround an edge of the display area DD_DA.

The display device DD may have various shapes. The display device DD in a plan view, i.e., when viewed along a third direction DR3, may have a closed shape including straight and/or curved sides. For example, the display device DD may have a shape such as a polygon, circle, semicircle, or ellipse.

The display device DD may be employ in or as an electronic device providing a video display function, such as a portable computer, a mobile phone, a smart phone, a tablet personal computer, a smart watch, a watch phone, a portable multimedia player (PMP), a navigation system, an ultra-mobile personal computer (UMPC), and the like. In addition, the display device DD may be employed in or as an electronic device such as a head mounted display (HMD), a virtual reality (VR) device, a mixed reality (MR) device, an augmented reality (AR) device, or any other device having a display surface.

In an embodiment, the display device DD may have a flat display surface that is parallel to a first direction DR1 and a second direction DR2. In another embodiment, the display device DD may have a display surface that is at least partially curved or rounded. In an embodiment, the display device DD may be bendable, foldable, or rollable. In these cases, the display device DD (or display panel DP) may include materials that are flexible.

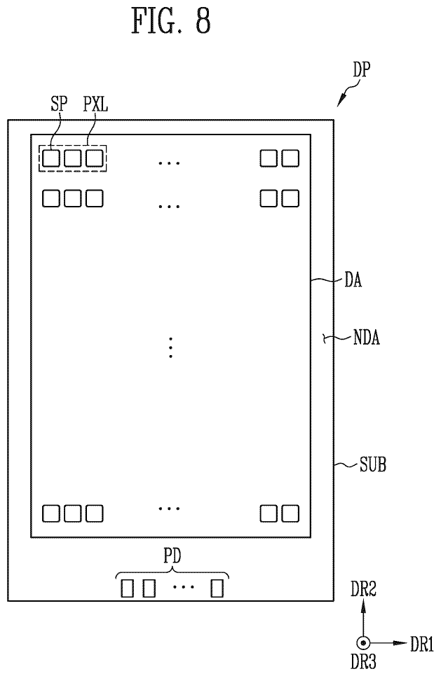

The display panel DP may be implemented as an organic light emitting display panel (OLED panel) that uses organic light emitting diodes as light emitting elements, an ultra-small light emitting diode display panel (micro-LED or nano-LED display panel) that uses ultra-small light emitting diodes as light emitting elements, a quantum dot organic light emitting display panel (QD OLED panel) that uses quantum dots and organic light emitting diodes, etc., but the display panel DP is not necessarily limited to these examples. The display panel DP is described in more detail below with reference to FIGS. 8 to 10.

A cover layer CV may be disposed on the display panel DP. The cover layer CV may protect the display panel DP from external impact, moisture, heat, etc. The cover layer CV may be made of a transparent material so that light emitted from the display panel DP may be transmitted through the cover layer CV. Example embodiments of the cover layer CV are described further below with reference is made to FIGS. 3 to 6.

Referring to FIG. 3, an embodiment of a cover layer CV_1 may include an anti-reflection layer A, B, and C. The anti-reflection layer A, B and C may include a substrate layer A, an intermediate layer B, and/or a surface layer C. The substrate layer A may be on the display panel DP. The intermediate layer B may be disposed on the substrate layer A. The surface layer C may be disposed on the intermediate layer B. The intermediate layer B may be disposed between the substrate layer A and the surface layer C. The substrate layer A may be disposed between the display panel DP and the intermediate layer B.

The substrate layer A may include a substrate high-refractive layer HA and a substrate low-refractive layer LA. The substrate high-refractive layer HA may be disposed on the display panel DP. The substrate low-refractive layer LA may be disposed on the substrate high-refractive layer HA. The substrate high-refractive layer HA may be disposed between the display panel DP and the substrate low-refractive layer LA.

A refractive index of the substrate high-refractive layer HA may be greater than a refractive index of the substrate low-refractive layer LA. Thereinafter, the refractive index refers to a refractive index for a wavelength of 550 nm. The refractive index of the substrate high-refractive layer HA may be 1.9 to 2.3 but is not necessarily limited thereto. The refractive index of the substrate low-refractive layer LA may be 1.4 to 1.7 but is not necessarily limited thereto.

The substrate high-refractive layer HA may include silicon nitride Si₃N₄. In some embodiments, the substrate high-refractive layer HA may include aluminum nitride AlN. The substrate low-refractive layer LA may include silicon dioxide SiO₂. According to an embodiment, the substrate low-refractive layer LA may include aluminum oxide Al₂O₃, aluminum oxynitride AlON, or silicon oxynitride SiON. However, the materials of the substrate high-refractive layer HA and substrate low-refractive layer LA are not necessarily limited thereto and may be variously changed to materials having refractive indices within the ranges described above.

A thickness of the substrate high-refractive layer HA in the third direction DR3 may be in a range from 5 nm to 70 nm. A thickness in the third direction DR3 of the substrate low-refractive layer LA may be in a range from 5 nm to 70 nm. When the thickness of the substrate high-refractive layer HA is 5 nm to 70 nm and the thickness of the substrate low-refractive layer LA is 5 nm to 70 nm, the reflectivity of the anti-reflection layer A, B, and C may be reduced, and the hardness thereof may be improved. In an embodiment, the thickness in the third direction DR3 of the substrate high-refractive layer HA may be smaller than the thickness in the third direction DR3 of the substrate low-refractive layer LA. For example, the thickness in the third direction DR3 of the substrate high-refractive layer HA may be about 20 nm, and the thickness in the third direction DR3 of the substrate low-refractive layer LA may be about 40 nm, but the thicknesses are not necessarily limited thereto.

The intermediate layer B may include a first high-refractive layer H1B and a first low-refractive layer L1B. The first high-refractive layer H1B may be disposed on the substrate layer A. The first high-refractive layer H1B may be disposed on the substrate low-refractive layer LA. The first low-refractive layer L1B may be disposed on the first high-refractive layer H1B. The first high-refractive layer H1B may be disposed between the substrate low-refractive layer LA and the first low-refractive layer L1B.

A refractive index of the first high-refractive layer H1B may be greater than a refractive index of the first low-refractive layer L1B. The refractive index of the first high-refractive layer H1B may be, but is not necessarily limited to, 1.9 to 2.3. The refractive index of the first low-refractive layer L1B may be, but is not necessarily limited to, 1.4 to 1.7.

The first high-refractive layer H1B may include Si₃N₄. In some embodiments, the first high-refractive layer H1B may include AlN. The first low-refractive layer L1B may include SiO₂. According to an embodiment, the first low-refractive layer L1B may include Al₂O₃, AlON, or SiON. However, the materials of the first high-refractive layer H1B and the first low-refractive layer L1B are not necessarily limited thereto and may be variously changed to materials having refractive indices within the ranges described above.

The first high-index layer H1B may include, but is not necessarily limited to, the same material as the substrate high-refractive layer HA. The first low-refractive layer L1B may include, but is not necessarily limited to, the same material as the substrate low-refractive layer LA.

The thickness in the third direction DR3 of the first high-refractive layer H1B may be 200 nm to 600 nm. The thickness of the first low-refractive layer L1B in the third direction DR3 may be 5 nm to 30 nm. When the thickness of the first high-refractive layer H1B is 200 nm to 600 nm and the thickness of the first low-refractive layer L1B is 5 nm to 30 nm, the reflectivity of the anti-reflection layer A, B, and C may be reduced, and the hardness thereof may be improved. In an embodiment, the thickness of the first high-refractive layer H1B in the third direction DR3 may be greater than the thickness of the first low-refractive layer L1B in the third direction DR3. For example, the thickness of the first high-refractive layer H1B in the third direction DR3 may be about 160 nm, and the thickness of the first low-refractive layer L1B in the third direction DR3 may be about 20 nm, but these thicknesses are not necessarily limited thereto.

The surface layer C may include a surface high-refractive layer HC and a surface low-refractive layer LC. The surface high-refractive layer HC may be disposed on the intermediate layer B. The surface high-refractive layer HC may be disposed on the first low-refractive layer L1B. The surface low-refractive layer LC may be disposed on the surface high-refractive layer HC. The surface high-refractive layer HC may be disposed between the first low-refractive layer L1B and the surface low-refractive layer LC.

The refractive index of the surface high-index layer HC may be greater than the refractive index of the surface low-index layer LC. The refractive index of the surface high-refractive layer HC may be, but is not necessarily limited to, 1.9 to 2.3. The refractive index of the surface low-refractive layer LC may be, but is not necessarily limited to, 1.4 to 1.7.

The surface high-refractive layer HC may include Si₃N₄. In some embodiments, the surface high-refractive layer HC may include AlN. The surface low-refractive layer LC may include SiO₂. According to an embodiment, the surface low-refractive layer LC may include Al₂O₃, AlON, SiON. However, the materials of the surface high-refractive layer HC and the surface low-refractive layer LC are not necessarily limited thereto and may be variously changed to materials having refractive indices within the ranges described above.

The surface high-index layer HC may include, but is not necessarily limited to, the same material as the substrate high-refractive layer HA and/or the first high-index layer H1B. The surface low-refractive layer LC may include, but is not necessarily limited to, the same material as the substrate low-refractive layer LA and/or the first low-refractive layer L1B.

The thickness in the third direction DR3 of the surface high-refractive layer HC may be 100 nm to 180 nm. The thickness in the third direction DR3 of the surface low-refractive layer LC may be 60 nm to 110 nm. When the thickness of the surface high-refractive layer HC is 100 nm to 180 nm and the thickness of the surface low-refractive layer LC is 60 nm to 110 nm, the reflectivity of the anti-reflection layer A, B, and C may be reduced, and the hardness thereof may be improved. In an embodiment, the thickness of the surface high-refractive layer HC in the third direction DR3 may be greater than the thickness of the surface low-refractive layer LC in the third direction DR3. For example, the thickness of the surface high-refractive layer HC in the third direction DR3 may be about 150 nm, and the thickness of the surface low-refractive layer LC in the third direction DR3 may be about 80 nm, but these thicknesses are not necessarily limited thereto.

In some embodiments, the intermediate layer B may be omitted. In this case, the surface layer C may be disposed directly on the substrate layer A. For example, the surface high-refractive layer HC may be directly disposed on the substrate low-refractive layer LA.

In an embodiment, an anti-fingerprint layer AF may be on the surface layer C. The anti-fingerprint layer AF may be applied as a special treatment to the surface layer C to improve touch sensitivity and resist smudges such as fingerprints, etc. The anti-fingerprint layer AF may provide water-repellent or oil-repellent functions to prevent contamination from outside the cover layer CV_1 and may make fingerprints less noticeable or easier to remove. The anti-fingerprint layer AF may include, but is not necessarily limited to, perfluoropolyether (PFPE).

Referring also to FIG. 2, an adhesive layer AD may be disposed between the display panel DP and the cover layer CV. The adhesive layer AD may be provided between the display panel DP and the cover layer CV to serve to bond the display panel DP and the cover layer CV. The adhesive layer AD may be disposed between the display panel DP and the substrate layer A. For example, an adhesive layer AD may be disposed between the display panel DP and the substrate high-refractive layer HA. One surface of the adhesive layer AD may be in contact with an upper surface of the display panel DP, and the other surface of the adhesive layer AD may be in contact with an upper surface of the substrate high-refractive layer HA.

The refractive index of the adhesive layer AD may be, but is not necessarily limited to, 1.4 to 1.7. The adhesive layer AD may include SiO₂. According to an embodiment, the adhesive layer AD may include Al₂O₃. However, the material of the adhesive layer AD is not necessarily limited thereto, and materials in the adhesive layer AD may be variously changed to provide a refractive index within the range described above.

The adhesive layer AD may include, but is not necessarily limited to, the same material as the substrate low-refractive layer LA, the first low-refractive layer L1B and/or the surface low-refractive layer LC. The thickness of the adhesive layer AD in the third direction DR3 may be 10 nm to 70 nm. When the thickness of the adhesive layer AD is 10 nm to 70 nm, the reflectivity of the cover layer CV may be reduced.

According to the above-described embodiment, by forming the thickness of the high-refractive layer and the low-refractive layer constituting each of the substrate layer A, the intermediate layer B, and/or the surface layer C, the reflectivity of the cover layer CV_1 (or anti-reflection layer) may be reduced to 0.8% and the hardness thereof may be improved. That is, a high-hardness cover layer CV_1 (or anti-reflection layer) with excellent optical properties may be provided.

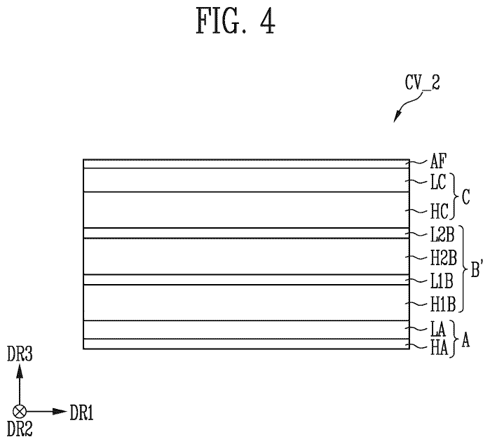

Referring to FIG. 4, a cover layer CV_2 may include anti-reflection layer A, B′, and C. The anti-reflection layer A, B′, and C may include a substrate layer A, an intermediate layer B′, and/or a surface layer C. The intermediate layer B′ may be disposed on the substrate layer A. The surface layer C may be disposed on the intermediate layer B′. The intermediate layer B′ may be disposed between the substrate layer A and the surface layer C. The substrate layer A and/or surface layer C of FIG. 4 may be substantially the same as the substrate layer A and/or surface layer C described above with reference to FIG. 3, and description of the substrate layer A or the surface layer C that is redundant with the description above may be omitted below.

The intermediate layer B′ may include a first high-refractive layer H1B, a first low-refractive layer L1B, a second high-refractive layer H2B, and/or a second low-refractive layer L2B. The first high-refractive layer H1B may be disposed on the substrate layer A. The first high-refractive layer H1B may be disposed on the substrate low-refractive layer LA. The first low-refractive layer L1B may be disposed on the first high-refractive layer H1B. The second high-refractive layer H2B may be disposed on the first low-refractive layer L1B. The second low-refractive layer L2B may be disposed on the second high-refractive layer H2B.

The refractive index of the second high-refractive layer H2B may be greater than the refractive index of the second low-refractive layer L2B. The refractive index of the second high-refractive layer H2B may be, but is not necessarily limited to, 1.9 to 2.3. The refractive index of the second low-refractive layer L2B may be, but is not necessarily limited to, 1.4 to 1.7.

The second high-refractive layer H2B may include Si₃N₄. In some embodiments, the second high-refractive layer H2B may include AlN. The second low-refractive layer L2B may include SiO₂. According to an embodiment, the second low-refractive layer L2B may include Al₂O₃, AlON, or SiON. However, the materials of the second high-refractive layer H2B and the second low-refractive layer L2B are not necessarily limited thereto and may be variously changed to provide the second low-refractive layer L2B with a refractive index within the range described above.

The second high-index layer H2B may include, but is not necessarily limited to, the same material as the substrate high-refractive layer HA, the first high-index layer H1B, and/or the surface high-index layer HC. The second low-refractive layer L2B may include, but is not necessarily limited to, the same material as the substrate low-refractive layer LA, the first low-refractive layer L1B, and/or the surface low-refractive layer LC.

A thickness in the third direction DR3 of the substrate high-refractive layer HA may be 5 nm to 70 nm. A thickness in the third direction DR3 of the substrate low-refractive layer LA may be 5 nm to 70 nm. When the thickness of the substrate high-refractive layer HA is 5 nm to 70 nm and the thickness of the substrate low-refractive layer LA is 5 nm to 70 nm, the reflectivity of the anti-reflection layer A, B′, and C may be reduced, and the hardness thereof may be improved.

In an embodiment, the thickness of the substrate high-refractive layer HA in the third direction DR3 may be smaller than the thickness of the substrate low-refractive layer LA in the third direction DR3. For example, the thickness of the substrate high-refractive layer HA in the third direction DR3 may be about 20 nm, and the thickness of the substrate low-refractive layer LA in the third direction DR3 may be about 30 nm, but these thicknesses are not necessarily limited thereto.

The thickness of the first high-refractive layer H1B in the third direction DR3 may be 200 nm to 600 nm. The thickness of the first low-refractive layer L1B in the third direction DR3 may be 5 nm to 30 nm. The thickness of the second high-refractive layer H2B in the third direction DR3 may be 200 nm to 600 nm. The thickness of the second low-refractive layer L2B in the third direction DR3 may be 5 nm to 30 nm. When the thickness of the first high-refractive layer H1B and/or the second high-refractive layer H2B is 200 nm to 600 nm, and the thickness of the first low-refractive layer L1B and/or the second low-refractive layer L2B is 5 nm to 30 nm, the reflectivity of the anti-reflection layer A, B′, and C may be reduced and the hardness thereof may be improved.

In an embodiment, the thickness of the first high-refractive layer H1B in the third direction DR3 may be greater than the thickness of the first low-refractive layer L1B in the third direction DR3. The thickness of the second high-refractive layer H2B in the third direction DR3 may be greater than the thickness of the second low-refractive layer L2B in the third direction DR3. For example, the thickness of the first high-refractive layer H1B in the third direction DR3 may be about 180 nm, and the thickness of the first low-refractive layer L1B in the third direction DR3 may be about 10 nm, but these thicknesses are not necessarily limited thereto. For example, the thickness of the second high-refractive layer H2B in the third direction DR3 may be about 190 nm, and the thickness of the second low-refractive layer L2B in the third direction DR3 may be about 20 nm, but these thicknesses are not necessarily limited thereto.

The thickness of the surface high-refractive layer HC in the third direction DR3 may be 100 nm to 180 nm. The thickness of the surface low-refractive layer LC in the third direction DR3 may be 60 nm to 110 nm. When the thickness of the surface high-refractive layer HC is 100 nm to 180 nm and the thickness of the surface low-refractive layer LC is 60 nm to 110 nm, the reflectivity of the anti-reflection layer A, B′, and C may be reduced, and the hardness thereof may be improved. In an embodiment, the thickness of the surface high-refractive layer HC in the third direction DR3 may be greater than the thickness of the surface low-refractive layer LC in the third direction DR3. For example, the thickness of the surface high-refractive layer HC in the third direction DR3 may be about 160 nm, and the thickness of the surface low-refractive layer LC in the third direction DR3 may be about 90 nm, but these thicknesses are not necessarily limited thereto.

According to the above-described embodiment shown in FIG. 4, by forming the thickness of the high-refractive layer and the low-refractive layer constituting each of the substrate layer A, the intermediate layer B′, and/or the surface layer C, the reflectivity of the cover layer CV_2 (or anti-reflection layer) may be reduced to 0.9% and the hardness thereof may be improved. That is, as described above, it is possible to provide a high-hardness cover layer CV_2 (or anti-reflection layer) with excellent optical properties.

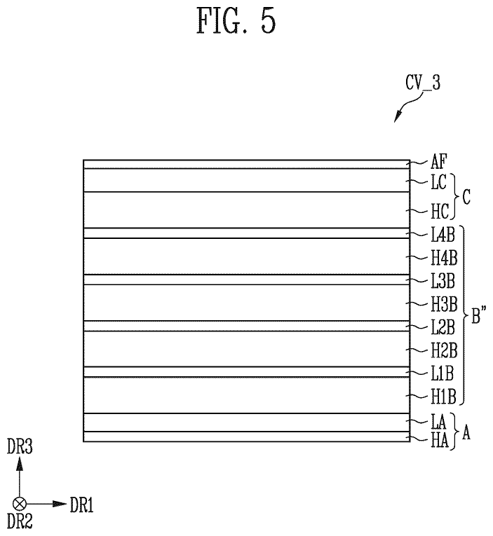

Referring to FIG. 5, a cover layer CV_3 may include an anti-reflection layer A, B″, and C. The anti-reflection layer A, B″, and C may include a substrate layer A, an intermediate layer B″, and/or a surface layer C. The intermediate layer B″ may be disposed on the substrate layer A. The surface layer C may be disposed on the intermediate layer B″. The intermediate layer B″ may be disposed between the substrate layer A and the surface layer C. The substrate layer A and/or surface layer C of FIG. 5 may be substantially the same as the substrate layer A and/or surface layer C of FIG. 3 and/or FIG. 4, and description of the substrate layer A or the surface layer C that is redundant with the description above may be omitted below.

The intermediate layer B″ may include a first high-refractive layer H1B, a first low-refractive layer L1B, a second high-refractive layer H2B, a second low-refractive layer L2B, a third high-refractive layer H3B, a third low-refractive layer L3B, a fourth high-refractive layer H4B, and/or a fourth low-refractive layer L4B. The first high-refractive layer H1B may be disposed on the substrate layer A. The first high-refractive layer H1B may be disposed on the substrate low-refractive layer LA. The first low-refractive layer L1B may be disposed on the first high-refractive layer H1B. The second high-refractive layer H2B may be disposed on the first low-refractive layer L1B. The second low-refractive layer L2B may be disposed on the second high-refractive layer H2B. The third high-refractive layer H3B may be disposed on the second low-refractive layer L2B. The third low-refractive layer L3B may be disposed on the third high-refractive layer H3B. The fourth high-refractive layer H4B may be disposed on the third low-refractive layer L3B. The fourth low-refractive layer L4B may be disposed on the fourth high-refractive layer H4B.

Some features of embodiments of the first high-refractive layer H1B, the first low-refractive layer L1B, the second high-refractive layer H2B, and the second low-refractive layer L2B are described above and may be applied in the embodiment of FIG. 5.

The refractive index of the third high-refractive layer H3B may be greater than the refractive index of the third low-refractive layer L3B. The refractive index of the third high-refractive layer H3B may be, but is not necessarily limited to, 1.9 to 2.3. The refractive index of the third low-refractive layer L3B may be, but is not necessarily limited to, 1.4 to 1.7.

The refractive index of the fourth high-refractive layer H4B may be greater than the refractive index of the fourth low-refractive layer L4B. The refractive index of the fourth high-refractive layer H4B may be, but is not necessarily limited to, 1.9 to 2.3. The refractive index of the fourth low-refractive layer L4B may be, but is not necessarily limited to, 1.4 to 1.7.

The third high-refractive layer H3B may include Si₃N₄. In some embodiments, the third high-refractive layer H3B may include AlN. The third low-refractive layer L3B may include SiO₂. According to an embodiment, the third low-refractive layer L3B may include Al₂O₃, AlON, or SiON. However, the materials of the third high-refractive layer H3B and the third low-refractive layer L3B are not necessarily limited thereto, and the materials in the third high-refractive layer H3B and the third low-refractive layer L3B may be variously changed to provide refractive indices within the ranges described above.

The fourth high-refractive layer H4B may include Si₃N₄. In some embodiments, the fourth high-refractive layer H4B may include AlN. The fourth low-refractive layer L4B may include SiO₂. According to an embodiment, the fourth low-refractive layer L4B may include Al₂O₃, AlON, or SiON. However, the materials of the fourth high-refractive layer H4B and the fourth low-refractive layer L4B are not necessarily limited thereto and may be variously changed to provide refractive indices within the ranges described above.

The third high-index layer H3B may include, but is not necessarily limited to, the same material as the substrate high-refractive layer HA, the first high-index layer H1B, the second high-index layer H2B, and/or the surface high-index layer HC. The third low-refractive layer L3B may include, but is not necessarily limited to, the same material as the substrate low-refractive layer LA, the first low-refractive layer L1B, the second low-refractive layer L2B, and/or the surface low-refractive layer LC.

The fourth high-refractive layer H4B may include, but is not necessarily limited to, the same material as the substrate high-refractive layer HA, the first high-refractive layer H1B, the second high-refractive layer H2B, the third high-refractive layer H3B, and/or the surface high-refractive layer HC. The fourth low-refractive layer L4B may include, but is not necessarily limited to, the same material as the substrate low-refractive layer LA, the first low-refractive layer L1B, the second low-refractive layer L2B, the third low-refractive layer L3B, and/or the surface low-refractive layer LC.

In an embodiment of the cover layer CV_3, a thickness of the substrate high-refractive layer HA in the third direction DR3 may be 5 nm to 70 nm. A thickness of the substrate low-refractive layer LA in the third direction DR3 may be 5 nm to 70 nm. When the thickness of the substrate high-refractive layer HA is 5 nm to 70 nm and the thickness of the substrate low-refractive layer LA is 5 nm to 70 nm, the reflectivity of the anti-reflection layer A, B″, and C may be reduced, and the hardness thereof may be improved. In an embodiment, the thickness of the substrate high-refractive layer HA in the third direction DR3 may be smaller than the thickness of the substrate low-refractive layer LA in the third direction DR3. For example, the thickness of the substrate high-refractive layer HA in the third direction DR3 may be about 20 nm, and the thickness of the substrate low-refractive layer LA in the third direction DR3 may be about 30 nm, but these thicknesses are not necessarily limited thereto.

The thickness of the first high-refractive layer H1B in the third direction DR3 may be 200 nm to 600 nm. The thickness of the first low-refractive layer L1B in the third direction DR3 may be 5 nm to 30 nm. The thickness of the second high-refractive layer H2B in the third direction DR3 may be 200 nm to 600 nm. The thickness of the second low-refractive layer L2B in the third direction DR3 may be 5 nm to 30 nm. The thickness of the third high-refractive layer H3B in the third direction DR3 may be 200 nm to 600 nm. The thickness of the third low-refractive layer L3B in the third direction DR3 may be 5 nm to 30 nm. The thickness of the fourth high-refractive layer H4B in the third direction DR3 may be 200 nm to 600 nm. The thickness of the fourth low-refractive layer L4B in the third direction DR3 may be 5 nm to 30 nm. When the thickness of each of the first high-refractive layer H1B, the second high-refractive layer H2B, the third high-refractive layer H3B, and/or the fourth high-refractive layer H4B is 200 nm to 600 nm, and the thickness of each of the first low-refractive layer L1B, the second low-refractive layer L2B, the third low-refractive layer L3B, and/or the fourth low-refractive layer L4B is 5 nm to 30 nm, the reflectivity of the anti-reflection layer A, B″, and C may be reduced and the hardness thereof may be improved.

In an embodiment, the thickness of the first high-refractive layer H1B in the third direction DR3 may be greater than the thickness of the first low-refractive layer L1B in the third direction DR3. The thickness of the second high-refractive layer H2B in the third direction DR3 may be greater than the thickness of the second low-refractive layer L2B in the third direction DR3. The thickness of the third high-refractive layer H3B in the third direction DR3 may be greater than the thickness of the third low-refractive layer L3B in the third direction DR3. The thickness of the fourth high-refractive layer H4B in the third direction DR3 may be greater than the thickness of the fourth low-refractive layer L4B in the third direction DR3. For example, the thickness of the first high-refractive layer H1B in the third direction DR3 may be about 170 nm, and the thickness of the first low-refractive layer L1B in the third direction DR3 may be about 10 nm, but these thicknesses are not necessarily limited thereto. The thickness of the second high-refractive layer H2B in the third direction DR3 may be about 200 nm, and the thickness of the second low-refractive layer L2B in the third direction DR3 may be about 10 nm, but these thicknesses are not necessarily limited thereto. The thickness of the third high-refractive layer H3B in the third direction DR3 may be about 180 nm, and the thickness of the third low-refractive layer L3B in the third direction DR3 may be about 10 nm, but these thicknesses are not necessarily limited thereto. The thickness of the fourth high-refractive layer H4B in the third direction DR3 may be about 180 nm, and the thickness of the fourth low-refractive layer L4B in the third direction DR3 may be about 20 nm, but these thicknesses are not necessarily limited thereto.

The thickness in the third direction DR3 of the surface high-refractive layer HC may be 100 nm to 180 nm. The thickness in the third direction DR3 of the surface low-refractive layer LC may be 60 nm to 110 nm. When the thickness of the surface high-refractive layer HC is 100 nm to 180 nm and the thickness of the surface low-refractive layer LC is 60 nm to 110 nm, the reflectivity of the anti-reflection layer A, B″, and C may be reduced, and the hardness thereof may be improved. In an embodiment, the thickness of the surface high-refractive layer HC in the third direction DR3 may be greater than the thickness of the surface low-refractive layer LC in the third direction DR3. For example, the thickness in the third direction DR3 of the surface high-refractive layer HC may be about 150 nm, and the thickness in the third direction DR3 of the surface low-refractive layer LC may be about 90 nm, but these thicknesses are not necessarily limited thereto.

According to the above-described embodiment, by forming the thicknesses of the high-refractive layer and the low-refractive layer constituting each of the substrate layer A, the intermediate layer B″, and/or the surface layer C, the reflectivity of the cover layer CV_3 (or anti-reflection layer) may be reduced to 0.9% and the hardness thereof may be improved. That is, as described above, it is possible to provide a high-hardness cover layer CV_3 (anti-reflection layer) with excellent optical properties.

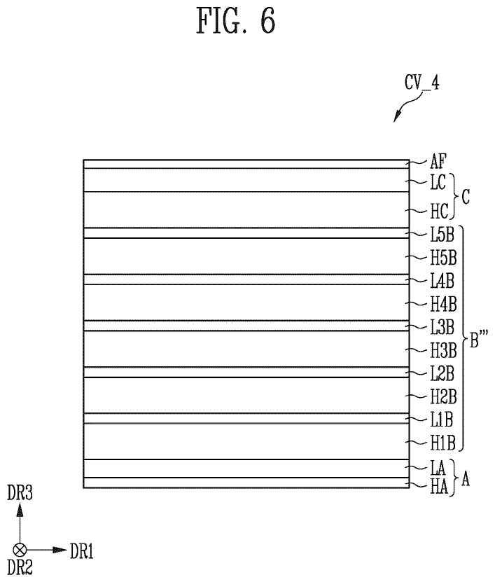

Referring to FIG. 6, a cover layer CV_4 may include an anti-reflection reflection layer A, B″′, and C. The anti-reflection layer A, B″′, and C may include a substrate layer A, an intermediate layer B″′, and/or a surface layer C. The intermediate layer B″′ may be disposed on the substrate layer A. The surface layer C may be disposed on the intermediate layer B″′. The intermediate layer B″′ may be disposed between the substrate layer A and the surface layer C. The substrate layer A and/or surface layer C of in the embodiment of FIG. 6 may be substantially the same as the substrate layer A and/or surface layer C of FIG. 3, FIG. 4, and/or FIG. 5, and description of the substrate layer A or the surface layer C that is redundant with the above description may be omitted below.

The intermediate layer B″′ may include a first high-refractive layer H1B, a first low-refractive layer L1B, a second high-refractive layer H2B, a second low-refractive layer L2B, a third high-refractive layer H3B, a third low-refractive layer L3B, a fourth high-refractive layer H4B, a fourth low-refractive layer L4B, a fifth high-refractive layer H5B, and/or a fifth low-refractive layer L5B. The first high-refractive layer H1B may be disposed on the substrate layer A. The first high-refractive layer H1B may be disposed on the substrate low-refractive layer LA. The first low-refractive layer L1B may be disposed on the first high-refractive layer H1B. The second high-refractive layer H2B may be disposed on the first low-refractive layer L1B. The second low-refractive layer L2B may be disposed on the second high-refractive layer H2B. The third high-refractive layer H3B may be disposed on the second low-refractive layer L2B. The third low-refractive layer L3B may be disposed on the third high-refractive layer H3B. The fourth high-refractive layer H4B may be disposed on the third low-refractive layer L3B. The fourth low-refractive layer L4B may be disposed on the fourth high-refractive layer H4B. The fifth high-refractive layer H5B may be disposed on the fourth low-refractive layer L4B. The fifth low-refractive layer L5B may be disposed on the fifth high-refractive layer H5B.

Some features of embodiments of the first high-refractive layer H1B, the first low-refractive layer L1B, the second high-refractive layer H2B, the second low-refractive layer L2B, the third high-refractive layer H3B, the third low-refractive layer L3B, the fourth high-refractive layer HB4, and the fourth low-refractive layer LB4 are described above and may be applied in the embodiment of FIG. 6.

The refractive index of the fifth high-refractive layer H5B may be greater than the refractive index of the fifth low-refractive layer L5B. The refractive index of the fifth high-refractive layer H5B may be, but is not necessarily limited to, 1.9 to 2.3. The refractive index of the fifth low-refractive layer L5B may be, but is not necessarily limited to, 1.4 to 1.7.

The fifth high-refractive layer H5B may include Si₃N₄. In some embodiments, the fifth high-refractive layer H5B may include AlN. The fifth low-refractive layer L5B may include SiO₂. According to an embodiment, the fifth low-refractive layer L5B may include Al₂O₃, AlON, and SiON. However, the materials of the fifth high-refractive layer H5B and the fifth low-refractive layer L5B are not necessarily limited thereto, and the materials may be variously changed to provide refractive indices within the ranges described above.

The fifth high-refractive layer H5B may include, but is not necessarily limited to, the same material as the substrate high-refractive layer HA, the first high-refractive layer H1B, the second high-refractive layer H2B, the third high-refractive layer H3B, the fourth high-refractive layer H4B, and/or the surface high-refractive layer HC. The fifth low-refractive layer L5B may include, but is not necessarily limited to, the same material as the substrate low-refractive layer LA, the first low-refractive layer L1B, the second low-refractive layer L2B, the third low-refractive layer L3B, the fourth low-refractive layer L4B, and/or the surface low-refractive layer LC.

In an embodiment of FIG. 6, a thickness in the third direction DR3 of the substrate high-refractive layer HA may be 5 nm to 70 nm. A thickness in the third direction DR3 of the substrate low-refractive layer LA may be 5 nm to 70 nm. When the thickness of the substrate high-refractive layer HA is 5 nm to 70 nm and the thickness of the substrate low-refractive layer LA is 5 nm to 70 nm, the reflectivity of the anti-reflection layer A, B″′, and C may be reduced, and the hardness thereof may be improved. In an embodiment, the thickness in the third direction DR3 of the substrate high-refractive layer HA may be smaller than the thickness in the third direction DR3 of the substrate low-refractive layer LA. For example, the thickness of the substrate high-refractive layer HA in the third direction DR3 may be about 20 nm, and the thickness of the substrate low-refractive layer LA in the third direction DR3 may be about 30 nm, but these thicknesses are not necessarily limited thereto.

The thickness in the third direction DR3 of the first high-refractive layer H1B may be 200 nm to 600 nm. The thickness in the third direction DR3 of the first low-refractive layer L1B may be 5 nm to 30 nm. The thickness of the second high-refractive layer H2B in the third direction DR3 may be 200 nm to 600 nm. The thickness of the second low-refractive layer L2B in the third direction DR3 may be 5 nm to 30 nm. The thickness of the third high-refractive layer H3B in the third direction DR3 may be 200 nm to 600 nm. The thickness of the third low-refractive layer L3B in the third direction DR3 may be 5 nm to 30 nm. The thickness of the fourth high-refractive layer H4B in the third direction DR3 may be 200 nm to 600 nm. The thickness of the fourth low-refractive layer L4B in the third direction DR3 may be 5 nm to 30 nm. The thickness of the fifth high-refractive layer H5B in the third direction DR3 may be 200 nm to 600 nm. The thickness of the fifth low-refractive layer L5B in the third direction DR3 may be 5 nm to 30 nm. When the thickness of each of the first high-refractive layer H1B, the second high-refractive layer H2B, the third high-refractive layer H3B, the fourth high-refractive layer H4B, and/or the fifth high-refractive layer H5B is 200 nm to 600 nm, and the thickness of each of the first low-refractive layer L1B, the second low-refractive layer L2B, the third low-refractive layer L3B, the fourth low-refractive layer L4B, and/or the fifth low-refractive layer L5B is 5 nm to 30 nm, the reflectivity of the anti-reflection layer A, B″′, and C may be reduced and the hardness thereof may be improved.

In an embodiment, the thickness of the first high-refractive layer H1B in the third direction DR3 may be greater than the thickness of the first low-refractive layer L1B in the third direction DR3. The thickness of the second high-refractive layer H2B in the third direction DR3 may be greater than the thickness of the second low-refractive layer L2B in the third direction DR3. The thickness of the third high-refractive layer H3B in the third direction DR3 may be greater than the thickness of the third low-refractive layer L3B in the third direction DR3. The thickness of the fourth high-refractive layer H4B in the third direction DR3 may be greater than the thickness of the fourth low-refractive layer L4B in the third direction DR3. The thickness of the fifth high-refractive layer H5B in the third direction DR3 may be greater than the thickness of the fifth low-refractive layer L5B in the third direction DR3. For example, the thickness of the first high-refractive layer H1B in the third direction DR3 may be about 170 nm, and the thickness of the first low-refractive layer L1B in the third direction DR3 may be about 10 nm, but these thicknesses are not necessarily limited thereto. The thickness of the second high-refractive layer H2B in the third direction DR3 may be about 180 nm, and the thickness of the second low-refractive layer L2B in the third direction DR3 may be about 10 nm, but these thicknesses are not necessarily limited thereto. The thickness of the third high-refractive layer H3B in the third direction DR3 may be about 190 nm, and the thickness of the third low-refractive layer L3B in the third direction DR3 may be about 10 nm, but these thicknesses are not necessarily limited thereto. The thickness of the fourth high-refractive layer H4B in the third direction DR3 may be about 180 nm, and the thickness of the fourth low-refractive layer L4B in the third direction DR3 may be about 10 nm, but these thicknesses are not necessarily limited thereto. The thickness of the fifth high-refractive layer H5B in the third direction DR3 may be about 180 nm, and the thickness of the fifth low-refractive layer L5B in the third direction DR3 may be about 20 nm, but these thicknesses are not necessarily limited thereto.

The thickness of the surface high-refractive layer HC in the third direction DR3 may be 100 nm to 180 nm. The thickness of the surface low-refractive layer LC in the third direction DR3 may be 60 nm to 110 nm. When the thickness of the surface high-refractive layer HC is 100 nm to 180 nm and the thickness of the surface low-refractive layer LC is 60 nm to 110 nm, the reflectivity of the anti-reflection layer A, B″′, and C may be reduced, and the hardness thereof may be improved. In an embodiment, the thickness of the surface high-refractive layer HC in the third direction DR3 may be greater than the thickness of the surface low-refractive layer LC in the third direction DR3. For example, the thickness of the surface high-refractive layer HC in the third direction DR3 may be about 150 nm, and the thickness of the surface low-refractive layer LC in the third direction DR3 may be about 90 nm, but these thicknesses are not necessarily limited thereto.

According to the above-described embodiment, by forming the thickness of the high-refractive layer and the low-refractive layer constituting each of the substrate layer A, the intermediate layer B″′, and/or the surface layer C, the reflectivity of the cover layer CV_4 (or anti-reflection layer) may be reduced to 0.8% and the hardness thereof may be improved. That is, as described above, it is possible to provide a high-hardness cover layer CV_4 (or anti-reflection layer) with excellent optical properties.

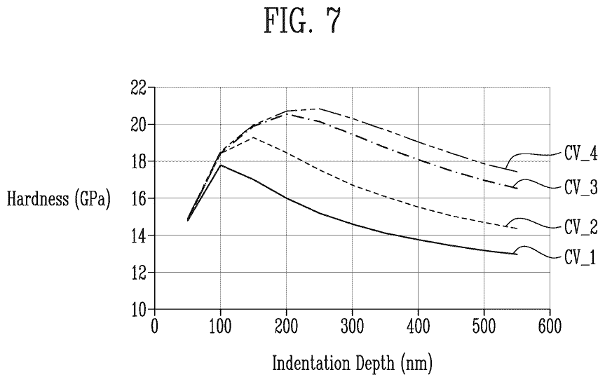

FIG. 7 is a graph showing a hardness of cover layers CV_1, CV_2, CV_3, and CV_4 according to embodiments described above. FIG. 7 particularly shows dependence the indentation hardness (GPa) on indentation depth (nm) for embodiments of the cover layers CV_1, CV_2, CV_3, and CV_4.

Referring to FIG. 7, the maximum hardness of the cover layer CV_1 of FIG. 3 is about 18 Gpa, the maximum hardness of the cover layer CV_2 of FIG. 4 is about 19 Gpa, the maximum hardness of the cover layer CV_3 of FIG. 5 is about 20 Gpa, and the maximum hardness of the cover layer CV_4 of FIG. 6 is about 21 Gpa. Forming the thickness of the high-refractive layers and the low-refractive layers constituting each of the substrate layer, the intermediate layer, and/or the surface layer in accordance with the embodiments described above may reduce the reflectivity of a cover layer (or the anti-reflection layer) to 1% or less and may improve the hardness thereof. That is, a high-hardness cover layer (or anti-reflection layer) with excellent optical properties may be provided.

In an embodiment, the cover layers CV_1, CV_2, CV_3, and CV_4 may have different indentation depths that exhibit maximum hardness. That is, the indentation depth exhibiting the maximum hardness may vary depending on the composition of the high-refractive layers and the low-refractive layers in the intermediate layer of the cover layers. Therefore, the intermediate layer of a cover layer may be configured depending on the desired indentation depth, so that the hardness and anti-reflection properties may be optimized or selected according to the use of the cover layer.

FIG. 8 is a plan view showing a display panel DP according to an embodiment. The display panel DP may be or may be used in a portable electronic device such as a mobile phone, smartphone, tablet personal computer (PC), mobile communication terminal, electronic notebook, e-book, portable multimedia player (PMP), navigation system, and ultra mobile PC (UMPC). Alternatively, the display panel DP may be or may be used in a larger device such as a television (TV), laptop, monitor, billboards, Internet of Things (IoT), or the like. According to an embodiment, the display panel DP may also be used in a wearable device such as a smart watch, watch phone, glasses-type display, or head mounted display (HMD). According to an embodiment, the electronic device DP may also be used in a dashboard of a vehicle, center information display (CID) on the center fascia or dashboard of a vehicle, a mirror display that replace a side view mirror of a vehicle, or display screen arranged on the rear side of a seat to serve as an entertainment device for back seat passengers in a vehicle.

Referring to FIG. 8, the display panel DP may include a display area DA and a non-display area NDA. The display panel DP may display an image through the display area DA. The non-display area NDA may be disposed around the display area DA.

The display panel DP may include a substrate SUB, sub-pixels SP, and/or pads PD.

The sub-pixels SP are disposed in the display area DA on the substrate SUB. The sub-pixels SP may be arranged in a matrix with rows and columns respectively extending in in the first direction DR1 and the second direction DR2. However, the embodiments are not limited thereto. For example, the sub-pixels SP may be arranged in zigzag shapes extending in the first direction DR1 and the second direction DR2. For example, the sub-pixels SP may be disposed in a pentile shape or pattern. The first direction DR1 may be a row direction, and the second direction DR2 may be a column direction. Two or more sub-pixels among the sub-pixels SP may constitute one pixel PXL.

Components for controlling sub-pixels SP may be disposed in the non-display area NDA on the substrate SUB. For example, wires connected to sub-pixels SP, such as gate lines and data lines, may be disposed or originate in the non-display area NDA.

Pads PD may be disposed in the non-display area NDA on the substrate SUB. The pads PD may be electrically connected to the sub-pixels SP through the wires. For example, the pads PD may be connected to the sub-pixels SP through the data lines.

The pads PD may interface the display panel DP to other components of the display device DD. In an embodiment, voltages and signals necessary for the operation of components included in the display panel DP may be provided from a driver integrated circuit through the pads PD. For example, the data lines may be connected to the driver integrated circuit through the pads PD. For example, power voltages may be received from the driver integrated circuit through the pads PD.

In an embodiment, a circuit board may be electrically connected to the pads PD using a conductive adhesive material, such as an anisotropic conductive film. The circuit board may be a flexible circuit board or a flexible film made of a flexible material. The driver integrated circuit may be mounted on a circuit board and electrically connected to the pads PD.

In embodiments, the display area DA may have various shapes. The display area DA may have a perimeter with a closed loop shape including straight and/or curved sides. For example, the display area DA may have a shape such as a polygon, circle, semicircle, or ellipse.

In an embodiment, the display panel DP may have a flat display surface. In another embodiment, the display panel DP may have an at least partially round display surface. In an embodiment, the display panel DP may be bendable, foldable, or rollable. In these cases, the display panel DP and/or the substrate SUB may include materials with flexible properties.

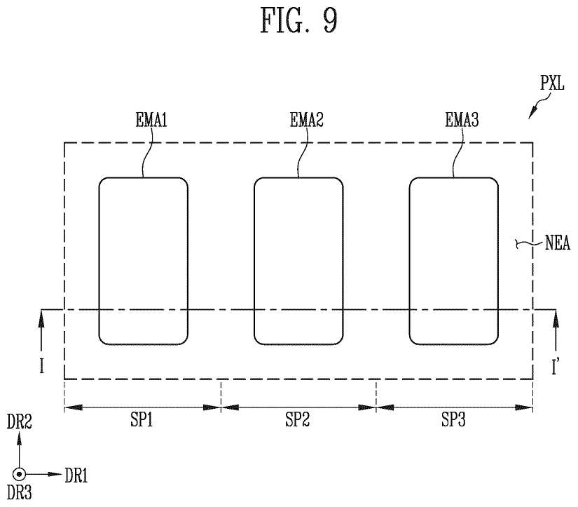

FIG. 9 is a plan view showing a pixel according to an embodiment.

Referring to FIG. 9, a pixel PXL may include first to third sub-pixels SP1 to SP3 arranged along the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

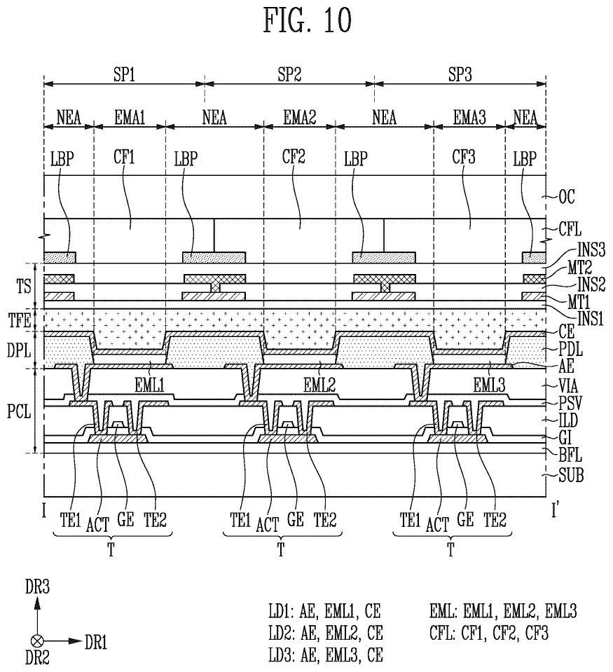

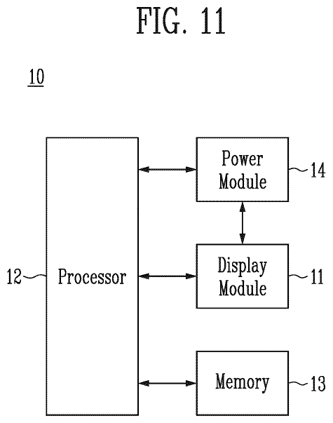

The first emission area EMA1 may be an area where light is emitted from a first light-emitting layer EML1 (see FIG. 10) of the first sub-pixel SP1. The second emission area EMA2 may be an area where light is emitted from a second light-emitting layer EML2 (see FIG. 10) of the second sub-pixel SP2. The third emission area EMA3 may be an area where light is emitted from a third light-emitting layer EML3 (see FIG. 10) of the third sub-pixel SP3.

FIG. 10 is a cross-sectional view of an embodiment of the pixel PXL taken along a line I-I′ of FIG. 9.

Referring to FIG. 10, the first to third sub-pixels SP1 to SP3 may respectively include the emission areas EMA1 to EMA3, which are sometimes generically referred to herein as emission areas EMA, and the non-emission area NEA may be disposed between the emission areas EMA of the first to third sub-pixels SP1 to SP3.

Each of the first to third sub-pixels SP1 to SP3 may include a pixel circuit layer PCL, a display element layer DPL, and/or a thin film encapsulation layer TFE sequentially disposed on the substrate SUB.

The substrate SUB may form a base surface. The substrate SUB may include a transparent insulating material and may transmit light. The substrate SUB may be a rigid substrate or a flexible substrate. A rigid substrate may be, for example, one of a glass substrate, a quartz substrate, a glass ceramic substrate, and a crystalline glass substrate. A flexible substrate may be one of a film substrate including a polymeric organic material and a plastic substrate. For example, the flexible substrate may include, but is not necessarily limited to, at least one material selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The pixel circuit layer PCL may include a pixel circuit provided on the substrate SUB. The pixel circuit layer PCL may include a sensor circuit provided on the substrate SUB.

The pixel circuit layer PCL may include a buffer layer BFL, a gate insulating layer GI, an interlayer insulating layer ILD, a passivation layer PSV, and/or a via layer VIA sequentially stacked in the third direction DR3 on the substrate SUB.

The buffer layer BFL may be an inorganic insulating layer including an inorganic material. The buffer layer BFL may include at least one metal oxide or insulator such as silicon nitride (SiN_{X}), silicon oxide (SiO_{X}), silicon oxynitride (SiO_{X}N_{Y}), aluminum oxide (AlO_{X}), and the like. The buffer layer BFL may be a single layer or may include multiple layers, including at least two layers. When the buffer layer BFL includes multiple layers, each layer may be formed of the same material or different materials. The buffer layer BFL may be omitted depending on materials and process conditions of the substrate SUB.

Transistors T may be disposed on the buffer layer BFL. Each transistor T may include an active pattern ACT, a gate electrode GE, a first transistor electrode TE1, and/or a second transistor electrode TE2.

Each active pattern ACT may be disposed on the buffer layer BFL. The active pattern ACT may include a polysilicon semiconductor. For example, the active pattern ACT may be formed through a low-temperature polysilicon process. However, the active pattern ACT is not necessarily limited thereto, and the active pattern ACT may be formed of an oxide semiconductor, a metal oxide semiconductor, etc.

Each active pattern ACT may include a channel region, a first contact region connected to one end of the channel region, and a second contact region connected to the other end of the channel region. The channel region, the first contact region, and the second contact region may be formed of a semiconductor layer that is undoped or doped with impurities. For example, the first contact region and the second contact region may be formed of a semiconductor layer doped with impurities, and the channel region may be formed of a semiconductor layer not doped with impurities. The impurities may include, for example, p-type impurities, but are not limited thereto. One of the first and second contact regions may be a source region, and the other may be a drain region.

The gate insulating layer GI may be disposed on the active pattern ACT. The gate insulating layer GI may be an inorganic layer or inorganic insulating layer including an inorganic material. For example, the gate insulating layer GI may include at least one of a metal oxide or insulator such as silicon nitride (SiN_{X}), silicon oxide (SiO_{X}), silicon oxynitride (SiO_{X}N_{Y}), aluminum oxide (AlO_{X}), and the like. However, the material of the gate insulating layer GI is not limited to the embodiments described above. According to an embodiment, the gate insulating layer GI may be formed of an organic layer or organic insulating layer including an organic material. The gate insulating layer GI may be a single layer or may include multiple layers including at least two layers.

The gate electrode GE of each transistor T may be disposed on the gate insulating layer GI. The gate electrode GE may overlap the channel region of the active pattern ACT. The gate electrode GE may be formed as a single layer using only material or a mixture of materials selected from the group consisting of copper (Cu), molybdenum (Mo), tungsten (W), aluminum neodymium (AlNd), titanium (Ti), aluminum (Al), silver (Ag), and alloys thereof, or may be formed as a double layer or multilayer structure using low-resistance materials such as molybdenum (Mo), titanium (Ti), copper (Cu), aluminum (Al), or silver (Ag) to reduce wiring resistance.

The interlayer dielectric layer ILD may be disposed on the gate electrode GE. The interlayer dielectric layer ILD may include the same material as the gate dielectric layer GI or may include one or more materials selected from the materials exemplified as constituent materials of the gate dielectric layer GI.

The first transistor electrode TE1 and the second transistor electrode TE2 may be disposed on and extend through the interlayer insulating layer ILD. The first transistor electrode TE1 of each transistor T may contact the first contact region of the active pattern ACT through a contact hole penetrating the interlayer insulating layer ILD and the gate insulating layer GI. If the first contact region is a source region, the first transistor electrode TE1 may be a source electrode.

The second transistor electrode TE2 of the transistor T may contact the second contact region at the other end of the active pattern ACT through a contact hole penetrating the interlayer insulating layer ILD and the gate insulating layer GI. If the second contact region is a drain region, the second transistor electrode TE2 may be a drain electrode.

Each of the first transistor electrode TE1 and the second transistor electrode TE2 may include the same material as the gate electrode GE or may include one or more materials selected from the materials exemplified as constituent materials of the gate electrode GE.

The passivation layer PSV may be disposed on the first transistor electrode TE1 and the transistor electrodes TE2. The passivation layer PSV (e.g., protective layer) may be an inorganic layer or inorganic insulating layer including an inorganic material or an organic layer or organic insulating layer including an organic material. The inorganic layer may include at least one material selected from a metal oxide, such as, for example, silicon oxide (SiO_{X}), silicon nitride (SiN_{X}), silicon oxynitride (SiO_{X}N_{Y}), or aluminum oxide (AlO_{X}). The organic layer may include, for example, at least one material selected from polyacrylates resin, epoxy resin, phenolic resin, polyamides resin, polyimides resin, unsaturated polyesters resin, polyphenylene ethers resin, polyphenylene sulfides resin, and benzocyclobutene resin.

In some embodiments, the passivation layer PSV may include, but is not limited to, the same material as the interlayer dielectric ILD. The passivation layer PSV may be a single layer or may include multiple layers, including at least two layers.

The via layer VIA may be disposed on the passivation layer PSV. The via layer VIA may include the same material as the passivation layer PSV or may include one or more materials selected from the materials exemplified as constituent materials of the passivation layer PSV. In an embodiment, the via layer VIA may be an organic layer made of an organic material.

The display element layer DPL may be disposed on the pixel circuit layer PCL. The display element layer DPL may include light emitting elements LD1, LD2, and LD3 that emit light. The first to third sub-pixels SP1 to SP3 may respectively include the first to third light emitting elements LD1 to LD3.

The first light emitting element LD1 may include an anode electrode AE, the first light-emitting layer EML1, and a cathode electrode CE. The second light emitting element LD2 may include an anode electrode AE, the second light-emitting layer EML2, and a cathode electrode CE. The third light emitting element LD3 may include an anode electrode AE, the third light-emitting layer EML3, and a cathode electrode CE. For example, the first to third light emitting elements LD1 to LD3 may be front-emitting organic light emitting elements.

The respective anode electrodes AE of the sub-pixels SP may be disposed in the emission areas EMA of the sub-pixels and may be spaced apart from each other. The anode electrode AE of each sub-pixel SP may be electrically connected to the first transistor electrode TE1 of the transistor T of each sub-pixel SP through a contact hole penetrating the via layer VIA and the passivation layer PSV.

A bank PDL may overlie portions of the anode electrodes AE. The bank PDL may define or partition the emission area EMA of each sub-pixel SP. The bank PDL may include openings, and each opening may partially expose the anode electrode AE of a sub-pixel SP.

The bank PDL may be an organic insulating layer made of organic material. The organic material may include acrylic resin, epoxy resin, phenolic resin, polyamide resin, polyimide resin, and the like.

According to an embodiment, the bank PDL may include a light absorbing material or may be coated with a light absorbing agent to absorb light introduced from the outside. For example, the bank PDL may contain a carbon-based black pigment. However, the bank PDL is not necessarily limited thereto, and the bank PDL may also include opaque metal materials such as chromium (Cr), molybdenum (Mo), an alloy of molybdenum and titanium (MoTi), tungsten (W), vanadium (V), niobium (Nb), tantalum (Ta), manganese (Mn), cobalt (Co), or nickel (Ni) with high light absorption.

The emitting layer EML of each sub-pixel SP may be disposed on the anode electrode AE of the sub-pixel SP where the anode electrode is exposed by the bank PDL. The cathode electrode CE may be disposed on the emitting layer EML. The cathode electrode CE may extend across the first to third sub-pixels SP1 to SP3. For example, the cathode electrode CE may be provided as a common electrode, but embodiments are not necessarily limited thereto.

The cathode electrode CE may be formed of a metal layer such as silver (Ag), magnesium (Mg), aluminum (Al), platinum (Pt), palladium (Pd), gold (Au), nickel (Ni), neodymium (Nd), iridium (Ir), chromium (Cr), an alloy thereof, and/or a transparent conductive layer such as indium tin oxide (ITO), indium zinc oxide (IZO), zinc oxide (ZnO), or indium tin zinc oxide (ITZO). According to an embodiment, the cathode electrode CE may be formed of multiple layers, including at least two layers including a thin metal layer, for example, a triple layer of ITO/Ag/ITO.

The thin film encapsulation layer TFE may be disposed on the display element layer DPL. The thin film encapsulation layer TFE may have a single-layer structure or a multi-layer structure. The thin film encapsulation layer TFE may include an insulating layer covering the light emitting elements LD1, LD3, and LD3. The thin-film encapsulation layer TFE may include at least one inorganic layer and at least one organic layer. For example, the thin film encapsulation layer TFE may have a structure in which inorganic and organic layers are alternately stacked. For example, the thin film encapsulation TFE layer may include a first inorganic layer, an organic layer disposed on the first inorganic layer, and a second inorganic layer disposed on the organic layer.

A sensing layer TS may be disposed on the thin film encapsulation layer TFE. The sensing layer TS may include a first insulating layer INS1, a first conductive layer MT1, a second insulating layer INS2, a second conductive layer MT2, and/or a third insulating layer INS3.

The first insulating layer INS1 may be disposed on the thin film encapsulation layer TFE. The first insulating layer INS1 may be an inorganic insulating layer including an inorganic material. The inorganic insulating layer may include an inorganic insulating material such as silicon oxide (SiO_{X}), silicon nitride (SiN_{X}), silicon oxynitride (SiO_{X}N_{Y}), aluminum oxide (Al_{X}O_{Y}), titanium oxide (TiOₓ), tantalum oxide (Ta_{X}O_{Y}), hafnium oxide (HfO_{X}), or zinc oxide (ZnO_{X}). According to the embodiment, the first insulating layer INS1 may be omitted or may be a top layer of the thin film encapsulation layer TFE.

The first conductive layer MT1 may be disposed on the first insulating layer INS1. The first conductive layer MT1 may be partially opened so as not to overlap the light emitting elements LD1, LD2, and LD3 of the sub-pixels SP. For example, the first conductive layer MT1 may overlap the non-emission area NEA around the emission areas EMA.

The first conductive layer MT1 may include a metal layer or a transparent conductive layer. For example, the metal layer may include molybdenum, titanium, copper, aluminum, and alloys thereof. The transparent conductive layer may include, but is not necessarily limited to, one of indium tin oxide (ITO), indium zinc oxide (IZO), zinc oxide (ZnO), indium tin zinc oxide (ITZO), PEDOT, and metal nanowires. The first conductive layer MT1 may form a connecting electrode connecting the sensing electrodes.

The second insulating layer INS2 may be disposed on the first conductive layer MT1. The second insulating layer INS2 may include the same material as the first insulating layer INS1 described above or may include one or more materials selected from the materials exemplified as constituent materials of the first insulating layer INS1.

The second conductive layer MT2 may be disposed on the second insulating layer INS2. The second conductive layer MT2 may be partially opened so as not to overlap the light emitting elements LD1, LD2, and LD3 of the sub-pixels SP. For example, the second conductive layer MT2 may overlap the non-emission area NEA around the emission areas EMA.

The second conductive layer MT2 may include the same material as the first conductive layer MT1 described above or may include one or more materials selected from the materials exemplified as the constituent materials of the first conductive layer MT1.

The second conductive layer MT2 may be electrically connected to the first conductive layer MT1 through a contact hole penetrating the second insulating layer INS2. The second conductive layer MT2 may form sensing electrodes.

The third insulating layer INS3 may be disposed on the second conductive layer MT2. The third insulating layer INS3 may be an organic insulating layer including an organic material. However, the third insulating layer INS3 is not necessarily limited thereto, and according to the embodiment, the third insulating layer INS3 may be an inorganic layer or may have a structure in which organic and inorganic layers are alternately stacked.

A light-shielding layer LBP may be disposed on the display element layer DPL, the thin film encapsulation layer TFE, and/or the sensing layer TS. The light-shielding layer LBP may include openings that overlap the light emitting elements LD1, LD2, and LD3. For example, the light-shielding layer LBP may be disposed to overlap the non-emission area NEA surrounding the emission areas EMA.

The light-shielding layer LBP may include a light-shielding material to prevent light leakage and color mixing effects. For example, the light-shielding layer LBP may include, but is not necessarily limited to, a black matrix. According to the embodiment, the light-shielding layer LBP may include carbon black CB and/or titanium black TiBK.

A color filter layer CFL may be disposed on the light-shielding layer LBP. The color filter layer CFL may include color filters CF1 to CF3 that match the color of each sub-pixel SP1 to SP3. By disposing color filters CF1 to CF3 corresponding to the colors of each of the first to third sub-pixels SP1 to SP3, a full-color image may be displayed.

The color filter layer CFL may include a first color filter CF1 disposed in the first sub-pixel SP1 to selectively transmit light emitted from the first sub-pixel SP1, a second color filter CF2 disposed in the second sub-pixel SP2 to selectively transmit light emitted from the second sub-pixel SP2, and a third color filter CF3 disposed in the third sub-pixel SP3 to selectively transmit light emitted from the third sub-pixel SP3.

In an embodiment, the first color filter CF1, the second color filter CF2, and the third color filter CF3 may be a red color filter, a green color filter, and a blue color filter, respectively, but are not necessarily limited thereto.

The first color filter CF1 may include a color filter material that selectively transmits light of a first color or red. For example, when the first sub-pixel SP1 is a red sub-pixel, the first color filter CF1 may include a red color filter material.

The second color filter CF2 may include a color filter material that selectively transmits light of a second color or green. For example, when the second sub-pixel SP2 is a green sub-pixel, the second color filter CF2 may include a green color filter material.

The third color filter CF3 may include a color filter material that selectively transmits light of a third color or blue. For example, when the third sub-pixel SP3 is a blue sub-pixel, the third color filter CF3 may include a blue color filter material.

An overcoat layer OC may be provided on the color filter layer CFL. The overcoat layer OC may include a variety of materials suitable for protecting layers thereunder from foreign substances such as dust, moisture, etc. For example, the overcoat layer OC may include at least one of an inorganic insulating layer and an organic insulating layer. For example, the overcoat layer OC may include epoxy, but embodiments are not limited thereto. An anti-reflection layer in accordance with any of the embodiments described above may be attached to the overcoat layer OC or formed in or on the overcoat layer OC.

A display device according to an embodiment is applicable to various types of electronic devices. In an embodiment, an electronic device includes the above-described display device and may further include other modules or devices having additional functions in addition to the display device.

FIG. 11 is a block diagram of an electronic device according to an embodiment. Referring to FIG. 11, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

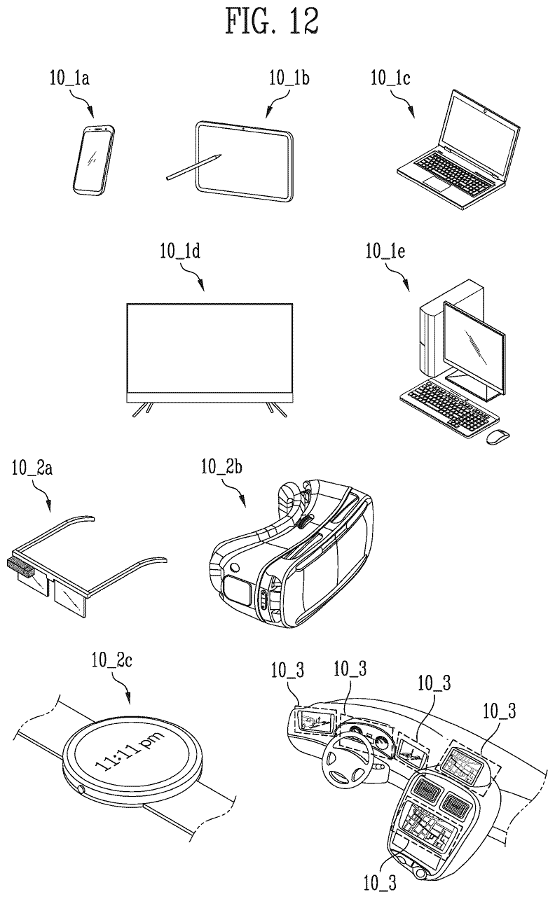

FIG. 12 shows schematic views of various embodiments of an electronic device.

Referring to FIG. 12, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although specific embodiments and applications are described herein, other embodiments and variations may be derived from the above description. Accordingly, the spirit of the present invention is not limited to these embodiments but extends to the scope of the claims set forth below, various obvious modifications, and equivalents.

What is claimed is:

1. An anti-reflection layer comprising:
a substrate layer including a substrate high-refractive layer and a substrate low-refractive layer; and
a surface layer disposed on the substrate layer and including a surface high-refractive layer and a surface low-refractive layer, wherein
a thickness of the substrate high-refractive layer is 5 nm to 70 nm,
a thickness of the substrate low-refractive layer is 5 nm to 70 nm,
a thickness of the surface high-refractive layer is 100 nm to 180 nm, and
a thickness of the surface low-refractive layer is 60 nm to 110 nm.

2. The anti-reflection layer of claim 1, further comprising
an intermediate layer disposed between the substrate layer and the surface layer and including a first high-refractive layer and a first low-refractive layer.

3. The anti-reflection layer of claim 2, wherein
a thickness of the first high-refractive layer is 20 nm to 600 nm.

4. The anti-reflection layer of claim 2, wherein
a thickness of the first low-refractive layer is 5 nm to 30 nm.

5. The anti-reflection layer of claim 2, wherein
the intermediate layer further includes a second high-refractive layer on the first low-refractive layer and a second low-refractive layer on the second high-refractive layer.

6. The anti-reflection layer of claim 5, wherein
a thickness of the second high-refractive layer is 20 nm to 600 nm.

7. The anti-reflection layer of claim 5, wherein
a thickness of the second low-refractive layer is 5 nm to 30 nm.

8. The anti-reflection layer of claim 1, wherein
a refractive index of each of the substrate high-refractive layer and the surface high-refractive layer is 1.9 to 2.3.

9. The anti-reflection layer of claim 1, wherein
a refractive index of each of the substrate low-refractive layer and the surface low-refractive layer is 1.4 to 1.7.

10. A display device comprising:
a display panel;
a substrate layer disposed on the display panel and including a substrate high-refractive layer and a substrate low-refractive layer; and
a surface layer disposed on the substrate layer and including a surface high-refractive layer and a surface low-refractive layer, wherein
a thickness of the substrate high-refractive layer is 5 nm to 70 nm,
a thickness of the substrate low-refractive layer is 5 nm to 70 nm,
a thickness of the surface high-refractive layer is 100 nm to 180 nm, and
a thickness of the surface low-refractive layer is 60 nm to 110 nm.

11. The display device of claim 10, further comprising
an intermediate layer disposed between the substrate layer and the surface layer and including a first high-refractive layer and a first low-refractive layer.

12. The display device of claim 11, wherein
a thickness of the first high-refractive layer is 20 nm to 600 nm.

13. The display device of claim 11, wherein
a thickness of the first low-refractive layer is 5 nm to 30 nm.

14. The display device of claim 11, wherein
the intermediate layer further includes a second high-refractive layer on the first low-refractive layer and a second low-refractive layer on the second high-refractive layer.

15. The display device of claim 14, wherein
a thickness of the second high-refractive layer is 20 nm to 600 nm.

16. The display device of claim 14, wherein
a thickness of the second low-refractive layer is 5 nm to 30 nm.

17. The display device of claim 10, further comprising
an anti-fingerprint layer on the surface layer.

18. The display device of claim 10, further comprising
an adhesive layer between the display panel and the substrate layer, and
wherein a thickness of the adhesive layer is 10 nm to 70 nm.

19. The display device of claim 18, wherein
a refractive index of the adhesive layer is 1.4 to 1.7.

20. An electronic device comprising:
a processor to provide input image data; and
a display device to display an image based on the input image data,
wherein the display device comprises:
a display panel;
a substrate layer disposed on the display panel and including a substrate high-refractive layer and a substrate low-refractive layer; and
a surface layer disposed on the substrate layer and including a surface high-refractive layer and a surface low-refractive layer, wherein
a thickness of the substrate high-refractive layer is 5 nm to 70 nm,
a thickness of the substrate low-refractive layer is 5 nm to 70 nm,
a thickness of the surface high-refractive layer is 100 nm to 180 nm, and
a thickness of the surface low-refractive layer is 60 nm to 110 nm.
